(19) United States
(12) Patent Application Publication
(10) Pub. No.: US 2026/0190739 A1
(43) Pub. Date: Jul. 2, 2026

(54) Display Device

(71) Applicant: LG Display Co., Ltd., Seoul (KR)

(72) Inventors: Binn Kim, Paju-si (KR); Taehee Ko, Paju-si (KR)

(21) Appl. No.: 19/423,092

(22) Filed: Dec. 17, 2025

(30) Foreign Application Priority Data
Dec. 30, 2024 (KR) 10-2024-0200398

(51) Int. Cl. H10K 59/38; H10K 59/122; H10K 59/80

(52) U.S. Cl. CPC H10K 59/38; H10K 59/122; H10K 59/8792

(57) ABSTRACT

A display device presented herein comprises a pixel area including a first sub-pixel and a transmissive area. The first sub-pixel includes the auxiliary color filter disposed under the light emitting layer. The auxiliary color filter extends from the pixel area and is also disposed in a partial area of the transmissive area adjacent to the pixel area.

### CROSS-REFERENCE TO RELATED APPLICATION

The present application claims priority to Republic of Korea Patent Application No. 10-2024-0200398, filed on Dec. 30, 2024, which is hereby incorporated by reference in its entirety.

### BACKGROUND

### Field

The present disclosure relates to a double-sided apparatus and particularly to, for example, without limitation, a double-sided display device.

### Description of Related Art

As an information society develops, a demand for a display device for displaying an image is increasing in various forms. Accordingly, various display devices such as a liquid crystal display (LCD), a plasma display panel (PDP), and an organic light emitting display (OLED) have recently been used.

Among the display devices, the organic light emitting display device is a self-luminous type, has better viewing angle and contrast ratio than the liquid crystal display (LCD), and has an advantage of being lightweight and thin because a separate backlight is not required and power consumption is advantageous. In addition, the organic light emitting display device has an advantage of being driven with a low DC voltage, having a fast response speed, and especially low manufacturing cost.

In addition, a transparent display device is also used in which an object can be seen from a rear of the OLED device when an image is not displayed by providing a transmissive area in some areas of such an OLED device. Recently, research has been conducted to improve the color and clarity of the transmissive area.

### SUMMARY

The present disclosure has been made in view of the above problems and other limitations associated with the related art.

Accordingly, embodiments of the present disclosure are directed to a display device with improved color and clarity of transmissive area

In accordance with one or more embodiments of the present disclosure, the above and other technical effects can be accomplished by the provision of a display device comprising a pixel area including a first sub-pixel and a second sub-pixel, and a transmissive area adjacent to the pixel area, and wherein the first sub-pixel and the second sub-pixel include a first insulating layer on a substrate, a first electrode and a bank on the first insulating layer, and a light emitting layer on the first electrode and the bank, wherein the first sub-pixel includes an auxiliary color filter disposed under the light emitting layer, and the second sub-pixel includes a color filter and a black matrix disposed on the light emitting layer, and wherein the auxiliary color filter extends from the pixel area and is also disposed in a partial area of the transmissive area adjacent to the pixel area.

It is to be understood that both the foregoing general description and the following detailed description are examples and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description explain the principle of the disclosure. In the drawings:

FIG. 1 is a circuit diagram of a display device according to one or more embodiments of the present disclosure.

FIG. 2 is a plan view of a display device according to one or more embodiments of the present disclosure.

FIG. 3 is a cross-sectional view of a display device according to one or more embodiments of the present disclosure, which is a cross-sectional view taken along line A-A′ of FIG. 2.

FIG. 4 is a cross-sectional view of a display device according to a first embodiment of the present disclosure, which is taken along line B-B′ of FIG. 2.

FIG. 5 is a cross-sectional view of a display device according to a second embodiment of the present disclosure, which is taken along line B-B′ of FIG. 2.

FIG. 6 is a cross-sectional view of a display device according to a third embodiment of the present disclosure, which is taken along line B-B′ of FIG. 2.

FIG. 7 is a cross-sectional view of a display device according to a fourth embodiment of the present disclosure, which is taken along line B-B′ of FIG. 2.

FIG. 8 is a plan view of a display device according to one or more embodiments of the present disclosure.

FIG. 9 is a plan view of a display device according to one or more other embodiments of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

Advantages and features of the present disclosure, and implementation methods thereof, will be clarified through the following examples described with reference to the accompanying drawings. The present disclosure may, however, be embodied in different forms and should not be construed as limited to the examples set forth herein. Rather, these examples are provided so that the specification of the present disclosure will be thorough, complete, and fully convey the scope of the present disclosure to those skilled in the art.

A shape, a size, a ratio, an angle, and a number disclosed in the accompanying drawings for describing the examples of the present disclosure are merely illustrative and, thus, the present disclosure is not limited to the illustrated details. Unless stated otherwise, like reference numerals refer to like elements throughout the specification. In the following description, when the detailed description of the relevant known function or configuration is determined to unnecessarily obscure an important point of the present disclosure, the detailed description will be omitted. In a case where terms such as ‘comprise’, ‘have’, and ‘include’ described in the present disclosure are used, another portion can be added unless ‘only’ is used. The terms of a singular form can include plural forms unless referred to the contrary.

In interpreting the components, it is interpreted as including an error range even if there is no separate explicit description of an error range.

In describing a position relationship, for example, when the position relationship is described using terms such as ‘upon’, ‘above’, ‘below’ and ‘next to’, one or more portions can be disposed between two other portions unless ‘just’ or ‘direct’ is used. The terms, such as “below,” “lower,” “above,” “upper”, and the like, can be used herein to describe a relationship between elements as illustrated in the drawings. It will be understood that the terms are spatially relative and based on the orientation depicted in the drawings.

A description of a time relationship can include a case in which the temporal precedence relationship is described as “after”, “following”, or “before”, etc., and is not continuous unless “right away” or “directly”, is used.

Although the terms such as first, second, and the like are used to describe various components, these components are not limited by these terms. These terms are used only to distinguish one component from another. Therefore, a first component mentioned below can be a second component within a technical idea of a present disclosure.

It will be understood that, although the terms such as “first,” “second,” “A,” “B,” “(a),” and “(b)”, etc., can be used herein to describe various elements, these elements should not be limited by these terms. These terms are only used to distinguish one element from another. For example, a first element could be termed a second element, and, similarly, a second element could be termed a first element, without departing from the scope of the present disclosure. Further, the term “can” fully encompasses all the meanings and coverages of the term “may” and vice versa.

Features of each of the various examples of the present disclosure can be partially or entirely coupled or combined with each other, technically various interworking and driving are possible, and each of the examples can be independently implemented with respect to each other or can be implemented together in a related relationship.

Hereinafter, embodiments of the present disclosure will be described in detail with reference to the accompanying drawings. All the components of each display device/apparatus according to all embodiments of the present disclosure are operatively coupled and configured.

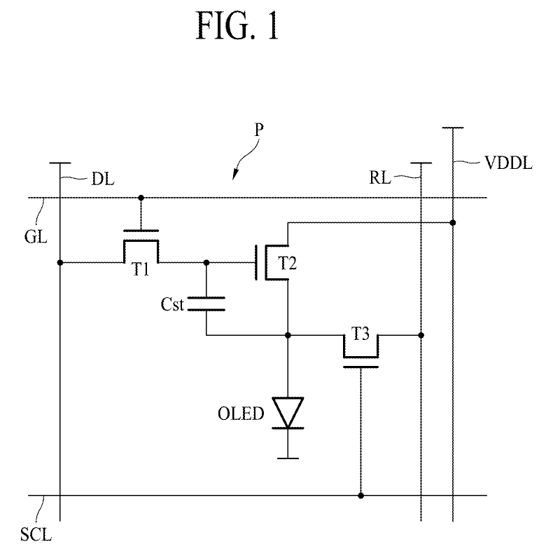

FIG. 1 is a circuit diagram of a display device according to one or more embodiments of the present disclosure.

Referring to FIG. 1, a display device according to one or more embodiments of the present disclosure may include a gate line GL, a data line DL, a high power line VDDL, a reference line RL, a sensing control line SCL, a switching thin film transistor T1, a driving thin film transistor T2, a sensing thin film transistor T3, a capacitor Cst, and a light emitting device OLED.

The gate line GL may supply a gate signal to a gate electrode of the switching thin film transistor T1. The data line DL may supply a data signal to a source electrode of the switching thin film transistor T1. The high power line VDDL may supply a high power to a drain electrode of the driving thin film transistor T2. The reference line RL may be connected to a drain electrode of the sensing thin film transistor T3.

The sensing control line SCL may supply a sensing control signal to a gate electrode of the sensing thin film transistor T3. In addition, the sensing control line SCL may be omitted. In this case, the gate electrode of the sensing thin film transistor T3 may be connected to the gate line GL to receive a sensing control signal from the gate line GL.

The switching thin film transistor T1 may be switched according to a gate signal supplied to the gate line GL to supply a data voltage supplied from the data line DL to the driving thin film transistor T2.

The driving thin film transistor T2 may be switched according to the data voltage supplied from the switching thin film transistor T1 to generate a data current from a high power source supplied from the high power source line VDDL and supply it to the light emitting device OLED.

The sensing thin film transistor T3 may supply a voltage of the driving thin film transistor T2 to the reference line RL in response to the sensing control signal supplied from the sensing control line SCL. In addition, in a sensing mode, the sensing thin film transistor T3 may sense a threshold voltage deviation of the driving thin film transistor T2, which is a cause of image quality deterioration.

The capacitor Cst may maintain a data voltage supplied to the driving thin film transistor T2 during one frame. The capacitor Cst may be connected to a gate electrode and a source electrode of the driving thin film transistor T2, respectively.

The light emitting device OLED may emit light according to the data current supplied from the driving thin film transistor T2. The light emitting device OLED may include a first electrode, a second electrode, and a light emitting layer disposed between the first electrode and the second electrode. The first electrode of the light emitting device OLED may be connected to a source electrode of the driving thin film transistor T2, and the second electrode of the light emitting device OLED may be connected to the low power line. Although not shown in FIG. 1, a low power line for supplying low power may be additionally provided to the second electrode of the light emitting device OLED. In addition, in the present disclosure, the power line may mean at least one of a high power line and a low power line.

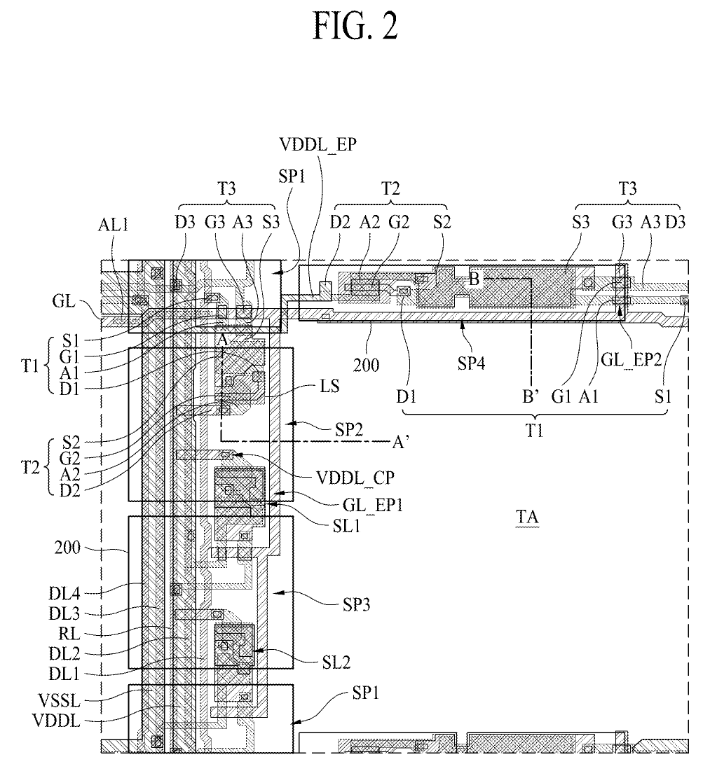

FIG. 2 is a plan view of a display device according to one or more embodiments of the present disclosure.

Referring to FIG. 2, a gate line GL may be disposed along a first direction. For example, the first direction may be a horizontal direction.

A partial region of the gate line GL may extend such that a first gate line extension portion GL_EP1 and a second gate line extension portion GL_EP2 may be disposed. The first gate line extension portion GL_EP1 and the second gate line extension portion GL_EP2 may be integrally formed with the gate line GL. The first gate line extension portion GL_EP1 may extend downward from the gate line GL, and the second gate line extension portion GL_EP2 may extend upward from the gate line GL.

The first gate line extension portion GL_EP1 may include a first portion and a second portion. The first portion may be a portion extending in a second direction from one side of the gate line GL. For example, the first portion may be a portion extending downward in the vertical direction from one side of the gate line GL. In addition, the second portion may be a portion extending in the first direction from the first portion. For example, the second portion may be a portion extending from the first portion to the left in the horizontal direction.

The first gate line extension portion GL_EP1 may include a structure in which a combination of the first portion and the second portion is repeated twice. Accordingly, the first gate line extension portion GL_EP1 may be extended to a plurality of sub-pixels arranged in the second direction. For example, the first gate line extension portion GL_EP1 may be extended to the third sub-pixel SP3 and the first sub-pixel SP1.

The second gate line extension portion GL_EP2 may extend in the second direction from the other side of the gate line GL. Accordingly, the second gate line extension portion GL_EP2 may extend to the other sub-pixel arranged in the first direction. For example, the second gate line extension portion GL_EP2 may extend to the fourth sub-pixel SP4.

The gate line GL may supply the gate signal to the second sub-pixel SP2, the first gate line extension portion GL_EP1 may supply the same gate signal to the third sub-pixel SP3 and the first sub-pixel SP1, and the second gate line extension portion GL_EP2 may supply the same gate signal to the fourth sub-pixel SP4. In this case, the first to third sub-pixels SP1, SP2, and SP3 may be arranged in the second direction, and the fourth sub-pixel SP4 may be arranged in the first direction. For example, the first to third sub-pixels SP1, SP2, and SP3 may be arranged in the vertical direction, and the fourth sub-pixel SP4 may be arranged in the horizontal direction from the right side of the first sub-pixel SP1.

A first active line AL1 may overlap the gate line GL. The first active line AL1 may extend in the same direction as the gate line GL. The first active line AL1 may be connected to the gate line GL through a contact hole. The first active line AL1 may not overlap the gate line extension portions GL_EP1 and GL_EP2.

A high power line VDDL, a low power line VSSL, data lines DL1, DL2, DL3, DL4, and a reference line RL may be disposed along the second direction. The fourth data line DL4, the third data line DL3, the reference line RL, the second data line DL2, and the first data line DL1 may be arranged in order, but the present invention is not limited thereto.

The data lines DL1, DL2, DL3, and DL4 may supply a data signal to each of the sub-pixels SP1, SP2, and SP3 SP4. The high power line VDDL may overlap the second data line DL2 and the reference line RL, and the low power line VSSL may overlap the third data line DL3 and the fourth data line DL4, but the present invention is not limited thereto.

The high power line VDDL may be connected to a high power line connection portion VDDL_CP. The high power line connection portion VDDL_CP may extend from the high power line VDDL in a first direction while being connected to the high power line VDDL through a contact hole. A high power source VDD may be supplied to the plurality of sub-pixels through the high power source line connection portion VDDL_CP. For example, the high power source VDD may be supplied to the first to third sub-pixels through the high power source line connection portion VDDL_CP.

A partial region of the high power line VDDL may extend so that the high power line extension portion VDDL_EP may be disposed. The high power line extension portion VDDL_EP may extend in a first direction from the high power line VDDL, and may extend to the fourth sub-pixel. The high power source VDD may be supplied to the fourth sub-pixel through the high power line extension portion VDDL_EP.

The data lines DL1, DL2, DL3, and DL4 and the reference line RL may be formed of the same material on the same layer. The data lines DL1, DL2, DL3, and DL4 and the reference line RL may be disposed below the gate line GL with an insulating layer therebetween.

The high power line VDDL and the low power line VSSL may be formed of the same material in the same layer. The high power line VDDL and the low power line VSSL may be disposed on an upper portion of the gate line GL with an insulating layer interposed therebetween.

The high power line connection portion VDDL_CP may be formed of the same material on the same layer as the gate line GL. The high power line extension portion VDDL_EP may be integrally formed with the high power line VDDL.

The high power line VDDL, the low power line VSSL, the data lines DL1, DL2, DL3, and DL4 and the reference line RL may intersect while overlapping the first active line AL1. A plurality of contact holes for connecting the first active line AL1 to the gate line GL may not overlap the high power line VDDL, the low power line VSSL, the data lines DL1, DL2, DL3, and DL4 and the reference line RL.

The first sub-pixel SP1 may be disposed above one side of the gate line GL while partially overlapping the gate line GL. The second sub-pixel SP2 and the third sub-pixel SP3 may be disposed below the first sub-pixel SP1. The fourth sub-pixel SP4 may be disposed above the other side of the gate line GL while partially overlapping the gate line GL. The fourth sub-pixel SP4 may face the first sub-pixel SP1.

The first to third sub-pixels SP1, SP2, and SP3 may overlap the high power line VDDL, the low power line VSSL, the data lines DL1, DL2, DL3, and DL4 and the reference line RL. In addition, the fourth sub-pixel SP4 may not overlap the high power line VDDL, the low power line VSSL, the data lines DL1, DL2, DL3, and DL4 and the reference line RL.

Each of the sub-pixels SP1, SP2, SP3, and SP4 may include an emission area, a line area, and a circuit area. In this case, the emission area may overlap the line area and the circuit area. In this case, the electroluminescent display device may be configured by a top emission type.

An area in which the sub-pixels SP1, SP2, SP3, and SP4 are disposed may be a pixel area PA. In addition, a right area of the second and third sub-pixels SP2 and SP3 and a lower area of the fourth sub-pixel SP4 may be a transmissive area TA through which external light may transmit.

The fourth data line DL4 and the third data line DL3 may be disposed adjacent to each other. In addition, other wires may not be disposed between the fourth data line DL4 and the third data line DL3. The third data line DL3 and the reference line RL may be disposed adjacent to each other. In addition, other wires may not be disposed between the third data line DL3 and the reference line RL. The reference line RL and the second data line DL2 may be disposed adjacent to each other. In addition, other wires may not be disposed between the reference line RL and the second data line DL2. The second data line DL2 and the first data line DL1 may be disposed adjacent to each other. In addition, other wires may not be disposed between the second data line DL2 and the first data line DL1.

The data lines DL1, DL2, DL3, and DL4 and the reference line RL may be disposed adjacent to each other. In addition, the high power line VDDL and the low power line VSSL are adjacent to each other, and may be disposed to overlap the data lines DL1, DL2, DL3, and DL4 and the reference line RL.

That is, various lines are adjacent to each other to form a line area, and a circuit area including a plurality of thin film transistors T1, T2, and T3 may be disposed adjacent to the line area. Accordingly, sizes of the line area and the circuit area may be reduced. Accordingly, a size of the emission area may be increased to improve resolution. In addition, a size of the transmissive area may be increased.

A switching thin film transistor T1, a driving thin film transistor T2, and a sensing thin film transistor T3 may be disposed in a circuit area of each of the four sub-pixels SP1, SP2, SP3, and SP4.

The switching thin film transistor T1 may include a first gate electrode G1, a first source electrode S1, a first drain electrode D1, and a first active layer A1.

In the second sub-pixel SP2, the first gate electrode G1 may be configured as a part of the gate line GL. In the first sub-pixel SP1 and the third sub-pixel SP3, the first gate electrode G1 may be configured as a part of the first gate line extension portion GL_EP1. In the fourth sub-pixel SP4, the first gate electrode G1 may be configured as a part of the second gate line extension portion GL_EP2.

The first source electrode S1 may be connected to the data lines DL1, DL2, DL3, and DL4 through a contact hole, and may be connected to one end of the first active layer A1 through a contact hole. The first drain electrode D1 may be formed on the same layer as the first source electrode S1 and may be connected to the other end of the first active layer A1 through a contact hole. The first source electrode S1 and the first drain electrode D1 may be formed on the same layer using the same material as the first gate electrode G1, but are not limited thereto. The first active layer A1 may be connected to the first source electrode S1 and the first drain electrode D1 through a contact hole, respectively, to function as an electron transfer channel.

The driving thin film transistor T2 may include a second gate electrode G2, a second source electrode S2, a second drain electrode D2, and a second active layer A2.

The second gate electrode G2 may be connected to the first drain electrode D1 of the switching thin film transistor T1. The second gate electrode G2 may be integrally formed with the first drain electrode D1, but is not limited thereto.

The second source electrode S2 may be connected to one end of the second active layer A2 through a contact hole. The second source electrode S2 may be connected to a light shielding layer LS through a contact hole. In addition, the second source electrode S2 may be electrically connected to a first electrode 210 through a contact hole.

The light shielding layer LS may be formed of the same material on the same layer as the data lines DL1, DL2, DL3, and DL4 and the reference line RL. The light shielding layer LS overlaps the second active layer A2 and may block external light from entering the second active layer A2.

In the first to third sub-pixels SP1, SP2, and SP3, the second drain electrode D2 may be connected to the high power line VDDL through the high power line connection portion VDDL_CP. In addition, in the fourth sub-pixel SP4, the second drain electrode D2 may be connected to the high power line VDDL through the high power line extension portion VDDL_EP. The second source electrode S2 and the second drain electrode D2 may be formed on the same layer of the same material as the second gate electrode G2, but are not limited thereto.

The second active layer A2 may be connected to the second source electrode S2 and the second drain electrode D2 through a contact hole, respectively, to function as an electron transfer channel. The second active layer A2 may be formed of the same material in the same layer as the first active layer A1.

The sensing thin film transistor T3 may include a third gate electrode G3, a third source electrode S3, a third drain electrode D3, and a third active layer A3.

In the second sub-pixel SP2, the third gate electrode G3 may be configured as a part of the gate line GL. In addition, in the first sub-pixel SP1 and the third sub-pixel SP3, the third gate electrode G3 may be configured as a part of the first gate line extension portion GL_EP1. In addition, in the fourth sub-pixel SP4, the third gate electrode G3 may be configured as a part of the second gate line extension portion GL_EP2.

The third source electrode S3 may be integrally formed with the second source electrode S2 of the driving thin film transistor T2. Alternatively, the third source electrode S3 may be connected to the light shielding layer LS through a contact hole, and may be electrically connected to the second source electrode S2 through the light shielding layer LS. The third source electrode S3 may be connected to one end of the third active layer A3 through a contact hole.

The third drain electrode D3 is formed on the same layer as the third source electrode S3, and may be connected to the other end of the third active layer A3 through a contact hole. Also, the third drain electrode D3 may be connected to the reference line RL through a contact hole.

The third active layer A3 may be connected to the third source electrode S3 and the third drain electrode D3 through a contact hole, respectively, to function as an electron transfer channel. The third active layer A3 may be formed of the same material in the same layer as the first active layer A1.

Accordingly, a size of the circuit area may be minimized or at least reduced by forming the thin film transistors T1, T2, and T3 in the first to third sub-pixels SP1, SP2, and SP3 at the highest density possible. Accordingly, sizes of the first to third sub-pixels SP1, SP2, and SP3 may be reduced, thereby improving resolution.

Meanwhile, since the thin film transistors T1, T2, and T3 of one sub-pixel are disposed in a high density in the plurality of sub-pixels SP1, SP2, and SP3, at least a portion of the thin film transistors T1, T2, and T3 of one sub-pixel may overlap the other sub-pixel SP1, SP2, and SP3 adjacent thereto

For example, at least one portion of the driving thin film transistor T2 of one sub-pixel may overlap another sub-pixel adjacent thereto. Specifically, parasitic capacitance may be generated between the driving thin film transistor T2 of one sub-pixel and the first electrode 210 of the other sub-pixel. In this case, a gate voltage of the driving thin film transistor T2 increases, and thus luminance may increase when the sub-pixel emits light. Accordingly, a gray scale defect may occur.

Therefore, to prevent parasitic capacitance, shielding layers SL1 and SL2 may be further disposed. In detail, shielding layers SL1 and SL2 may be further disposed in an area where at least one portion of the driving thin film transistor T2 of one sub-pixel overlaps another sub-pixel adjacent thereto.

For example, a first shielding layer SL1 may be disposed on at least a portion of the driving thin film transistor T2 of the third sub-pixel SP3 overlapping the second sub-pixel SP2, and a second shielding layer SL2 may be disposed on at least a portion of the driving thin film transistor T2 of the first sub-pixel SP1 overlapping the third sub-pixel SP3.

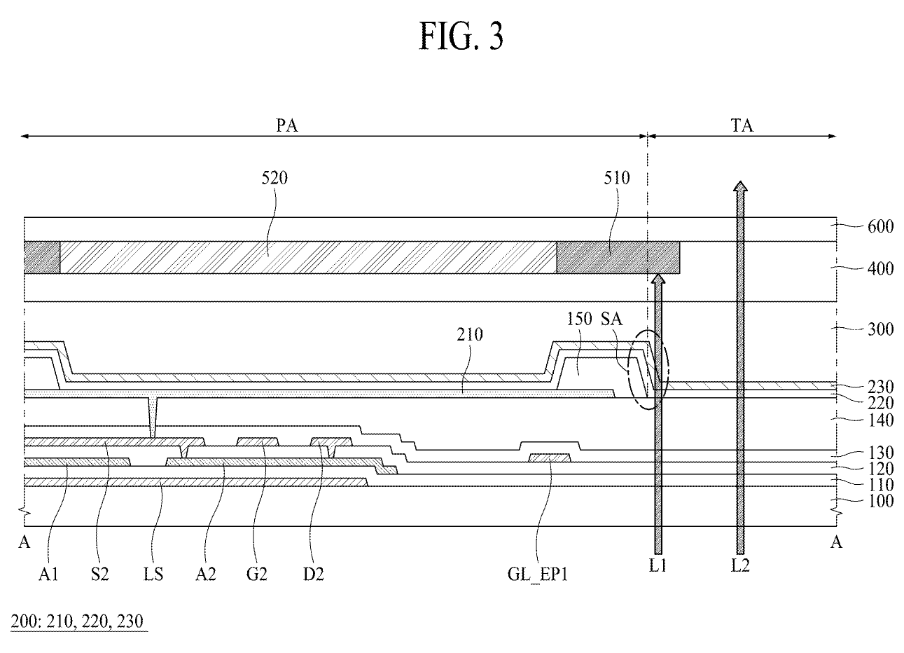

FIG. 3 is a cross-sectional view of a display device according to one or more embodiments of the present disclosure, which is taken along line A-A′ of FIG. 2. In detail, FIG. 3 illustrates a pixel area PA and a transmissive area TA of the second sub-pixel SP2. The second sub-pixel SP2 may be any one of a red sub-pixel, a green sub-pixel, and a blue sub-pixel.

Referring to FIG. 3, a first substrate 100 may include the pixel area PA and the transmissive area TA.

The first substrate 100 may be made of glass or plastic, but is not limited thereto. The display device according to one or more embodiments of the present disclosure may be made of a top emission type. Accordingly, the first substrate 100 may be formed of an opaque material as well as a transparent material.

A light shielding layer LS may be disposed on the first substrate 100. In addition, the light shielding layer LS may be disposed in the pixel area PA.

A first insulating layer 110 may be disposed on the light shielding layer LS. In addition, the first insulating layer 110 may be disposed in the pixel area PA and the transmissive area TA. The first insulating layer 110 may be formed of an inorganic insulating material.

A first active layer A1 and a second active layer A2 may be disposed on the first insulating layer 110. The first active layer A1 and the second active layer A2 may be disposed in the pixel area PA. At least a portion of the first active layer A1 and the second active layer A2 may overlap the light shielding layer LS. Accordingly, light incident from a lower portion of the first substrate 100 may be blocked by the light shielding layer LS, and may be prevented from being incident on at least a portion of the first active layer A1 and the second active layer A2.

A second insulating layer 120 may be disposed on the first active layer A1 and the second active layer A2. The second insulating layer 120 may be disposed in the pixel area PA and the transmissive area TA. The second insulating layer 120 may be disposed on an entire surface of the first substrate 100 except for a contact hole area. The second insulating layer 120 may be formed of an inorganic insulating material.

A second source electrode S2, the second gate electrode G2, the second drain electrode D2, and the first gate line extension portion GL_EP may be disposed on the second insulating layer 120. The second source electrode S2, the second gate electrode G2, the second drain electrode D2, and the first gate line extension portion GL_EP may be disposed in the pixel area PA. In addition, the second source electrode S2, the second gate electrode G2, the second drain electrode D2, and the first gate line extension portion GL_EP may be spaced apart from each other.

A second source electrode S2 may overlap the second active layer A2. In addition, the second source electrode S2 may be connected to one end area of the second active layer A2 through a contact hole disposed in the second insulating layer 120. The second source electrode S2 may overlap the first active layer A1, but is not connected to the first active layer A1.

A second gate electrode G2 may be disposed between the second drain electrode D2 and the second source electrode S2 while overlapping the second active layer A2.

A second drain electrode D2 may overlap the second active layer A2. In addition, the second drain electrode D2 may be connected to the other area of the second active layer A2 through a contact hole disposed in the second insulating layer 120.

The first gate line extension portion GL_EP may not overlap the first active layer A1 and the second active layer A2.

The second source electrode S2, the second gate electrode G2, the second drain electrode D2, and the first gate line extension portion GL_EP may be formed of the same material through the same process in the same layer.

A third insulating layer 130 may be disposed on the second source electrode S2, the second gate electrode G2, the second drain electrode D2, and the first gate line extension portion GL_EP. The third insulating layer 130 may be disposed in the pixel area PA and the transmissive area TA. The third insulating layer 130 may be disposed on the entire surface of the first substrate 100 except for the contact hole area. The third insulating layer 130 may be formed of an inorganic insulating material.

A fourth insulating layer 140 may be disposed on the third insulating layer 130. The fourth insulating layer 140 may be disposed in the pixel area PA and the transmissive area TA. In addition, the fourth insulating layer 140 may include a planarization layer made of an organic insulation material. The fourth insulating layer 140 may be formed of a plurality of insulating layers. For example, the fourth insulating layer 140 may have a two-layered structure of a passivation layer made of an inorganic material and a planarization layer made of an organic material.

A bank 150 and a light emitting device 200 may be disposed on the fourth insulating layer 140. The bank 150 and the light emitting device 200 may be disposed in the pixel area PA. In addition, the light emitting device 200 may include a first electrode 210, a light emitting layer 220 and a second electrode 230.

The first electrode 210 may be disposed on the fourth insulating layer 140. The first electrode 210 may function as an anode. The first electrode 210 may be connected to the second source electrode S2 through the contact hole, but is not limited thereto. For example, the first electrode 210 may be connected to the second drain electrode D2.

The bank 150 may be disposed on the fourth insulating layer 140. In addition, the bank 150 may cover both ends of the first electrode 210. It may be a partial area emission area of the first electrode 210 exposed by the bank 150. The bank 150 may be disposed at a boundary area between the pixel area PA and the transmissive area TA.

The light emitting layer 220 may be disposed on the first electrode 210 and the bank 150. The light emitting layer 220 may be continuously disposed between a plurality of sub-pixels. In this case, the light emitting layer 220 may emit white light. Alternatively, the light emitting layer 220 may include a blue light emitting layer, a green light emitting layer, and a red light emitting layer patterned for each of a plurality of sub-pixels.

The second electrode 230 may be disposed on the light emitting layer 220. The second electrode 230 may function as a cathode. In addition, the second electrode 230 may be disposed entirely on the plurality of sub-pixels and the boundary therebetween.

Since the display device according to one or more embodiments of the present disclosure is configured in a top emission type, the second electrode 230 may include a transparent conductive material such as an indium tin oxide (ITO) or an indium zinc oxide (IZO) to transmit light generated by the light emitting layer 220 to the upper side

An encapsulation layer 300 may be disposed on the light emitting device 200. The encapsulation layer 300 may compensate for a step difference caused by the light emitting device 200. The encapsulation layer 300 may include an organic insulating material such as an acrylic resin, an epoxy resin, a phenolic resin, a polyamide resin, or a polyimide resin. The encapsulation layer 300 may be disposed in the pixel area PA and the transmissive area TA.

An upper insulating layer 400, a black matrix 510, a color filter 520, and a second substrate 600 may be disposed on the encapsulation layer 300.

The second substrate 600 may be disposed in the pixel area PA and the transmissive area TA. The second substrate 600 may be made of glass or plastic, but is not limited thereto. Since the display device according to one or more embodiments of the present disclosure is made of a top emission type, a transparent material may be used as a material for the second substrate 600.

The black matrix 510 may be disposed between the second substrate 600 and the encapsulation layer 300. The black matrix 510 may be disposed in an area overlapping the bank 150. In the pixel area PA, the black matrix 510 may expose a portion of a lower surface of the second substrate 600. In addition, the black matrix 510 may be disposed in a partial area of the transmissive area TA.

The color filter 520 may be disposed between the second substrate 600 and the encapsulation layer 300. In the pixel area PA, the color filter 520 may be disposed on a lower surface of the second substrate 600 exposed by the black matrix 510. That is, the color filter 520 may be disposed in the pixel area PA. In addition, the color filter 520 may overlap the first electrode 210 exposed by the bank 150.

The color filter 520 may transmit only light of a specific wavelength band. For example, the color filter 520 may transmit only any one light of red, green, and blue.

The upper insulating layer 400 may be disposed under the black matrix 510 and the color filter 520. In addition, the upper insulating layer 400 may be disposed in the pixel area PA and the transmissive area TA.

Meanwhile, since the transmissive area TA does not include a metal layer, external light may be transmitted therethrough. Accordingly, the user can visually recognize an object disposed on the rear surface of the display device through the transmissive area TA.

Specifically, the external light may include a first light L1 and a second light L2. The first light L1 and the second light L2 may be incident on a lower portion of the first substrate 100 and may face the second substrate 600. The first light L1 may be incident on the transmissive area TA adjacent to the pixel area PA. In addition, the second light L2 may be incident on the transmissive area TA spaced apart from the pixel area PA than the first light L1.

In this case, a path of the first light L1 may overlap a step area SA, and a path of the second light L2 may not overlap the step area SA. The step area SA may be disposed in the transmissive area TA, and may be an area formed by a height difference between the fourth insulating layer 140 and the bank 150. The light emitting layer 220 and the second electrode 230 may extend from an upper surface of the bank 150 and may also be disposed in the step area SA.

In this case, a thickness of a material layer disposed in the step area SA may not be uniform. Accordingly, the first light L1 passing through the step area SA may be diffracted. When the diffracted first light L1 passes through the second substrate 600, color and sharpness of the transmissive area TA may be deteriorated. To solve this problem, the black matrix 510 may be extended to overlap the step area SA. Accordingly, the diffracted first light L1 may be absorbed by the black matrix 510, and the diffracted first light L1 may not pass through the second substrate 600.

On the other hand, a thickness of a material layer disposed in the transmissive area TA except for the step area SA may be uniform. Accordingly, the second light L2 that does not pass through the step area SA may stably transmit through the second substrate 600. Accordingly, deterioration of color and sharpness of the transmissive area TA may be prevented.

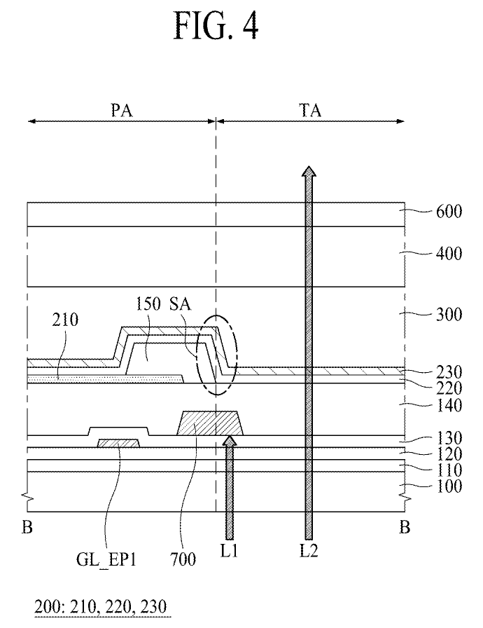

FIG. 4 is a cross-sectional view of a display device according to a first embodiment of the present disclosure, which is taken along line B-B′ of FIG. 2. In detail, FIG. 4 illustrates a boundary area between a pixel area PA and a transmissive area TA of the fourth sub-pixel SP4.

FIG. 3 discloses a case where the second sub-pixel SP2 is any one of a red sub-pixel, a green sub-pixel, and a blue sub-pixel. Accordingly, FIG. 3 discloses a structure in which the second sub-pixel SP2 includes the black matrix 510 and the color filter 520.

On the other hand, FIG. 4 discloses a case where the fourth sub-pixel SP4 is a white sub-pixel. Accordingly, the fourth sub-pixel SP4 may not include the color filter 520. In addition, since the fourth sub-pixel SP4 does not include the color filter 520, a partial area of the black matrix 510 may be removed from the fourth sub-pixel SP4.

Meanwhile, among the first to fourth sub-pixels SP1 toSP4, the fourth sub-pixel SP4 may have the largest area contacting the transmissive area TA. Accordingly, by removing the black matrix 510 from the area adjacent to the transmissive area TA in the fourth sub-pixel SP4, the transmittance of the transmissive area TA may be improved.

As described in FIG. 3, a step area SA may be formed by a height difference between the fourth insulating layer 140 and the bank 150. In addition, the first light L1 passing through the step area SA may be diffracted. However, since the fourth sub-pixel SP4 does not include the black matrix 510, the diffracted first light L1 may pass through the second substrate 600.

To solve this problem, an auxiliary color filter 700 may be additionally disposed in the fourth sub-pixel SP4. The auxiliary color filter 700 is disposed on the third insulating layer 130 and may overlap the step area SA. In addition, the fourth insulating layer 140 may cover the auxiliary color filter 700 and planarize an upper portion of the auxiliary color filter 700.

One side of the auxiliary color filter 700 may be disposed in the pixel area PA adjacent to the step area SA. In addition, one side of the auxiliary color filter 700 may overlap the first electrode 210, but is not limited thereto. For example, one side of the auxiliary color filter 700 may be adjacent to the first electrode 210. The other side of the auxiliary color filter 700 may be disposed in the transmissive area TA adjacent to the step area SA. Accordingly, the auxiliary color filter 700 may overlap the entire step area SA. In addition, the auxiliary color filter 700 may overlap an end of the bank 150 adjacent to the transmissive area TA.

In this case, since the auxiliary color filter 700 is disposed below the step area SA, the first light L1 may be incident on the auxiliary color filter 700 before the step area SA. The auxiliary color filter 700 may transmit only light of a specific wavelength band among the first light L1. Accordingly, diffraction of the first light L1 may be prevented, and thus color and sharpness of the transmissive area TA may be prevented from being deteriorated by the first light L1. Generally, a yellowish phenomenon occurs in the transmissive area TA, and thus the auxiliary color filter 700 may be preferably a blue color filter that transmits only blue light, but is not limited thereto.

Unlike the black matrix, the auxiliary color filter 700 may transmit light of a specific wavelength band without absorbing all of the first light L1. In addition, the auxiliary color filter 700 disposed under the first electrode 210 may not affect a driving of the pixel area PA. Accordingly, since an unnecessary area of the auxiliary color filter 700 may overlap the pixel area PA, an area in which the auxiliary color filter 700 is disposed in the transmission area TA may be minimized or at least reduced. Therefore, it is possible to minimize or at least reduce a decrease in the transmittance of the transmission area TA.

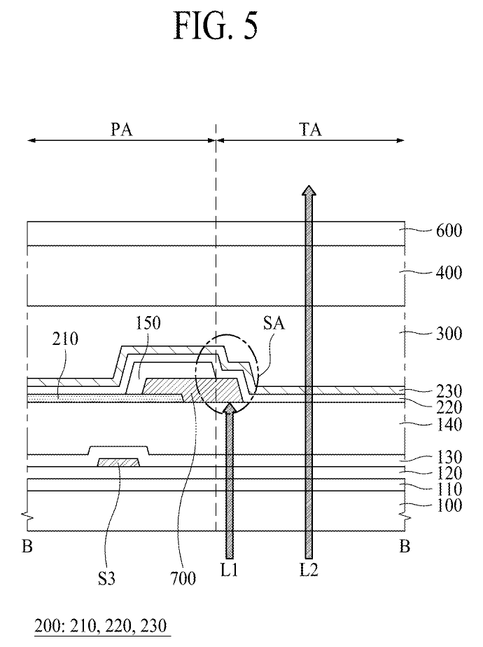

FIG. 5 is a cross-sectional view of a display device according to a second embodiment of the present disclosure, which is taken along line B-B′ of FIG. 2.

Referring to FIG. 5, an auxiliary color filter 700 may be disposed on the fourth insulating layer 140. Specifically, the auxiliary color filter 700 may be disposed between the first electrode 210 and the bank 150.

One side of the auxiliary color filter 700 may be disposed in the pixel area PA, and the other side of the auxiliary color filter 700 may be disposed in the transmissive area TA. In addition, one side of the auxiliary color filter 700 may be adjacent to the first electrode 210. For example, one side of the auxiliary color filter 700 may be disposed on the first electrode 210. That is, the auxiliary color filter 700 may cover a part of the upper surface of the first electrode 210, but is not limited thereto.

One side of the bank 150 may be disposed on the first electrode 210, and the other side of the bank 150 may be disposed on the auxiliary color filter 700. That is, a step area SA is formed by a height difference between the bank 150 and the auxiliary color filter 700, and the auxiliary color filter 700 may overlap the step area SA.

The light emitting layer 220 and the second electrode 230 may extend from the bank 150 and may be disposed on the auxiliary color filter 700. That is, the light emitting layer 220 and the second electrode 230 may be disposed in the step area SA between the bank 150 and the auxiliary color filter 700.

As described above with reference to FIG. 4, since the auxiliary color filter 700 is disposed below the step area SA, the first light L1 may be incident on the auxiliary color filter 700 before the step area SA. The auxiliary color filter 700 may transmit only light of a specific wavelength band among the first light L1. Accordingly, diffraction of the first light L1 may be prevented, and thus color and sharpness of the transmission area TA may be prevented from being deteriorated by the first light L1.

In addition, only light in a specific wavelength range of the first light L1 may be transmitted by the auxiliary color filter 700 in a step difference between the auxiliary color filter 700 and the fourth insulating layer 140.

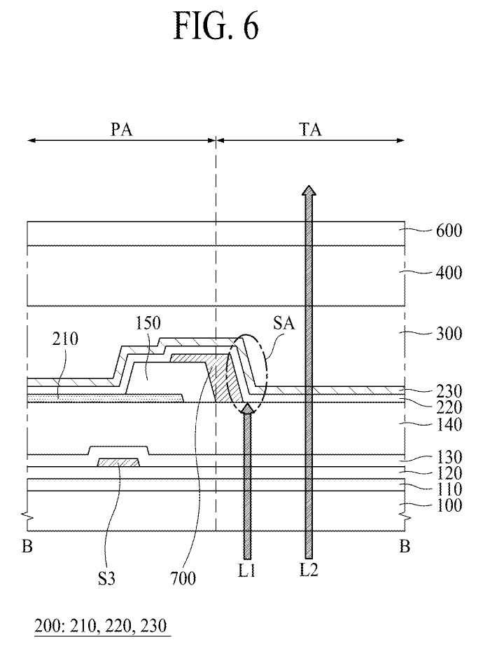

FIG. 6 is a cross-sectional view of a display device according to a third embodiment of the present disclosure, which is taken along line B-B′ of FIG. 2.

Referring to FIG. 6, an auxiliary color filter 700 may be disposed on a bank 150.

One side of the auxiliary color filter 700 may be disposed in the pixel area PA, and the other side of the auxiliary color filter 700 may be disposed in the transmissive area TA. In particular, one side of the auxiliary color filter 700 may be disposed on the bank 150, and the other side of the auxiliary color filter 700 may be disposed on the fourth insulating layer 140. That is, the auxiliary color filter 700 may cover a partial area of the bank 150 adjacent to the transmissive area TA. Accordingly, it is possible to prevent a step difference from being formed by the bank 150.

The light emitting layer 220 and the second electrode 230 may extend from the bank 150 and may be disposed on the auxiliary color filter 700. That is, the light emitting layer 220 and the second electrode 230 may be disposed in the step area SA between the auxiliary color filter 700 and the fourth insulating layer 140. Even in this case, the first light L1 is incident on the auxiliary color filter 700 first, and the auxiliary color filter 700 may transmit only light of a specific wavelength range among the first light L1. Accordingly, diffraction of the first light L1 may be prevented, and thus color and sharpness of the transmissive area TA may be prevented from being deteriorated by the first light L1.

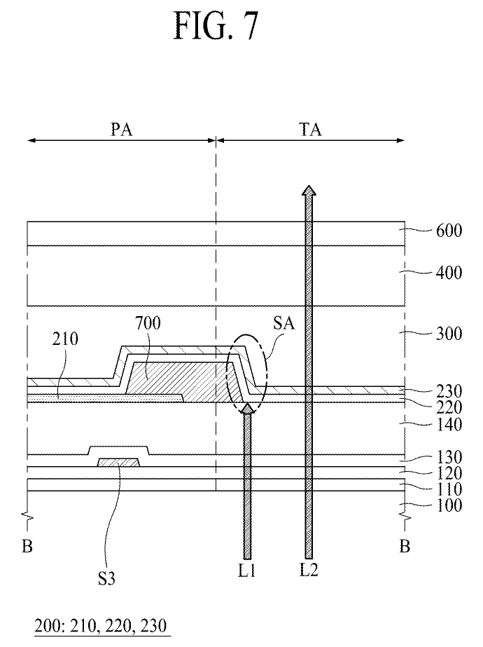

FIG. 7 is a cross-sectional view of a display device according to a fourth embodiment of the present disclosure, which is taken along line B-B′ of FIG. 2.

Referring to FIG. 7, the bank 150 may perform a function of the auxiliary color filter 700. That is, like the auxiliary color filter 700, the bank 150 includes a material having a color filter function and may transmit only light in a specific wavelength band.

The bank 150 may be disposed on the fourth insulating layer 140. One side of the bank 150 may be disposed in the pixel area PA, and the other side of the bank 150 may be disposed in the transmissive area TA. In particular, one side of the bank 150 may be disposed on the first electrode 210.

The step area SA may be formed by a height difference between the fourth insulating layer 140 and the bank 150. In this case, the first light L1 is incident on the bank 150, and the bank 150 may transmit only light of a specific wavelength band among the first light L1. Accordingly, diffraction of the first light L1 may be prevented, and thus color and sharpness of the transmissive area TA may be prevented from being deteriorated by the first light L1. As described above, it may be preferable that the bank 150 transmits blue light.

Although a structure of the additional auxiliary color filter 700 is omitted in FIG. 7, the structure of the auxiliary color filter 700 described in FIGS. 4-6 may be applied, and the bank 150 may be formed to include a material having a color filter function at the same time. In this case, the bank 150 and the auxiliary color filter 700 may include a material having the same color filter function, but are not limited thereto

In FIGS. 4-7, various embodiments of a formation position of the auxiliary color filter 700 have been disclosed, but are not limited thereto. For example, the auxiliary color filter 700 may be disposed between the light emitting layer 220 and the second electrode 230, or may also be disposed on the upper surface of the second electrode 230.

Meanwhile, it may not be desirable to form the auxiliary color filter 700 on a lower surface of the second substrate 600. In detail, the display device may be formed by a bonding process between the first substrate 100 and the second substrate 600. In the bonding process, an error may occur in a bonding position between the first substrate 100 and the second substrate 600. For example, when the auxiliary color filter 700 is formed on a lower surface of the second substrate 600, the auxiliary color filter 700 may be disposed in the emission area of the sub-pixel. Alternatively, the auxiliary color filter 700 may not be disposed in the step area. Accordingly, in order to prevent the auxiliary color filter 700 from being disposed at an unnecessary position, the auxiliary color filter 700 may be preferably formed on the first substrate 100.

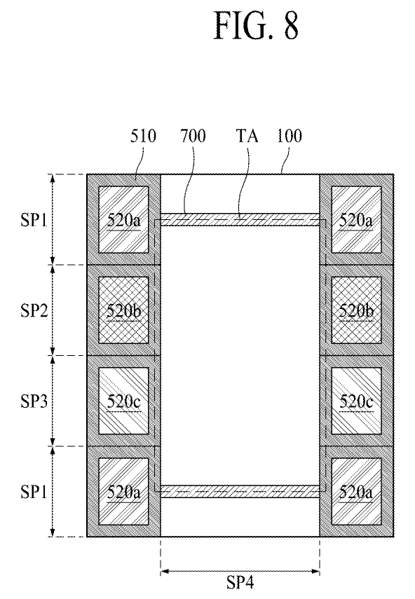

FIG. 8 is a plan view of a display device according to one or more embodiments of the present disclosure. Specifically, FIG. 8 illustrates the black matrix 510, the color filter 520, and the auxiliary color filter 700 disposed in the pixel area PA and the transmissive area TA.

Referring to FIG. 8, a first sub-pixel SP1, a second sub-pixel SP2, and a third sub-pixel SP3 may be sequentially disposed along a column direction. Each of the first sub-pixel SP1, the second sub-pixel SP2, and the third sub-pixel SP3 may include a black matrix 510 and a color filter 520.

In each of the first sub-pixel SP1, the second sub-pixel SP2, and the third sub-pixel SP3, the black matrix 510 may surround the color filter 520. The first sub-pixel SP1 may include a red color filter 520a, the second sub-pixel SP2 may include a green color filter 520b, and the third sub-pixel SP3 may include a blue sub-pixel 520c, but the present disclosure is not limited thereto.

The fourth sub-pixel SP4 may be disposed in the row direction from a right side of the first sub-pixel SP1. The fourth sub-pixel SP4 does not include the black matrix 510 and may include an auxiliary color filter 700. The auxiliary color filter 700 may be disposed in an area adjacent to the transmissive area TA. In addition, the auxiliary color filter 700 may not be disposed in an area adjacent to the first sub-pixel SP1, the second sub-pixel SP2, and the third sub-pixel SP3.

The transmissive area TA may be an area surrounded by the plurality of sub-pixels SP. The transmissive area TA may overlap some areas of the black matrix 510 and the auxiliary color filter 700. As a result, diffraction of light at an edge of the transmissive area TA may be prevented. Therefore, deterioration of color and sharpness of the transmissive area TA may be prevented.

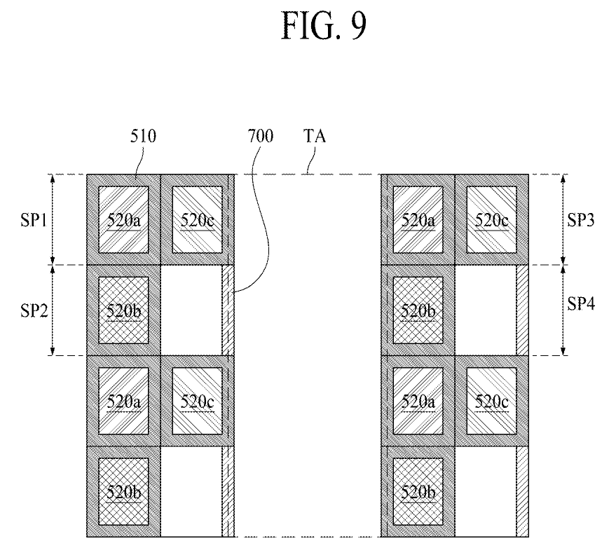

FIG. 9 is a plan view of a display device according to one or more other embodiments of the present disclosure.

Referring to FIG. 9, the first to fourth subpixels SP1 toSP4 are arranged in a quad structure. In detail, a second subpixel SP2 may be disposed below the first subpixel SP1. In addition, a third subpixel SP3 may be disposed at a right side of the first subpixel SP1, and a fourth subpixel SP4 may be disposed at the right side of the second subpixel SP2.

As described above, in each of the first sub-pixel SP1, the second sub-pixel SP2, and the third sub-pixel SP3, the black matrix 510 may surround the color filter 520. The first sub-pixel SP1 may include a red color filter 520a, the second sub-pixel SP2 may include a green color filter 520b, and the third sub-pixel SP3 may include a blue sub-pixel 520c, but the present disclosure is not limited thereto.

The fourth sub-pixel SP4 does not include the black matrix 510 and may include an auxiliary color filter 700. The auxiliary color filter 700 may be disposed in an area adjacent to the transmissive area TA. In addition, the auxiliary color filter 700 may not be disposed in an area adjacent to the first sub-pixel SP1, the second sub-pixel SP2, and the third sub-pixel SP3.

The transmissive area TA may be disposed at right sides of the second sub-pixel SP2 and the fourth sub-pixel SP4. The transmissive area TA may overlap some areas of the black matrix 510 and the auxiliary color filter 700. As a result, diffraction of light at an edge of the transmissive area TA may be prevented. Therefore, deterioration of color and sharpness of the transmissive area TA may be prevented.

It will be apparent to those skilled in the art that the present disclosure described above is not limited by the above-described embodiments and the accompanying drawings and that various substitutions, modifications and variations can be made in the present disclosure without departing from the technical idea or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device, comprising:
a pixel area including a first sub-pixel and a second sub-pixel; and
a transmissive area adjacent to the pixel area,
wherein the first sub-pixel and the second sub-pixel include:
a first insulating layer on a substrate;
a first electrode and a bank on the first insulating layer; and
a light emitting layer on the first electrode and the bank,
wherein the first sub-pixel includes an auxiliary color filter disposed under the light emitting layer,
wherein the second sub-pixel includes a color filter and a black matrix disposed on the light emitting layer, and
wherein the auxiliary color filter extends from the pixel area and is also disposed in a partial area of the transmissive area adjacent to the pixel area.

2. The display device of claim 1, wherein a first side of the auxiliary color filter is adjacent to the first electrode, and wherein a second side of the auxiliary color filter overlaps an end of the bank adjacent to the transmissive area.

3. The display device of claim 1, wherein the first sub-pixel further includes a second insulating layer on the first insulating layer,
wherein the auxiliary color filter is disposed between the first insulating layer and the second insulating layer, and
wherein the first electrode and the bank are disposed on the second insulating layer.

4. The display device of claim 1, wherein the auxiliary color filter is disposed on the first insulating layer, and wherein the auxiliary color filter is adjacent to the first electrode.

5. The display device of claim 4, wherein the auxiliary color filter is disposed between the first electrode and the bank, and wherein the auxiliary color filter covers a portion of an upper surface of the first electrode.

6. The display device of claim 5, wherein a first side of the bank is disposed on the upper surface of the first electrode, and wherein a second side of the bank is disposed on an upper surface of the auxiliary color filter.

7. The display device of claim 4, wherein the light emitting layer extends on the bank and is disposed on the auxiliary color filter.

8. The display device of claim 4, wherein the auxiliary color filter is disposed on the bank, and wherein the auxiliary color filter covers a partial area of the bank adjacent to the transmissive area.

9. The display device of claim 8, wherein a first side of the auxiliary color filter is disposed on the bank, and wherein a second side of the auxiliary color filter is disposed on the first insulating layer.

10. The display device of claim 8, wherein the light emitting layer extends on the bank and is disposed on the auxiliary color filter.

11. The display device of claim 1, wherein the bank transmits light in a specific wavelength band.

12. The display device of claim 1, wherein the auxiliary color filter transmits only blue light, and wherein the color filter transmits any one of red light, green light, and blue light.

13. The display device of claim 1, wherein the first sub-pixel emits white light, and wherein the second sub-pixel emits any one of red light, green light, and blue light.

14. The display device of claim 1, wherein the black matrix is not disposed in an area adjacent to the transmissive area in the first sub-pixel.

15. The display device of claim 1, wherein the black matrix extends from the pixel area and is also disposed in a partial area of the transmissive area adjacent to the pixel area.
